(19) United States
(12) Patent Application Publication
(10) Pub. No.: US 2002/0054480 A1
(43) Pub. Date: May 9, 2002

(54) ENHANCED THERMAL COUPLING FOR ELECTRONIC BOARDS

(76) Inventor: IONEL JITARU, TUCSON, AZ (US)

Correspondence Address: GARTH JANKE, BIRDWELL, JANKE, & DURANDO, PLC, 1925 STANDARD INSURANCE CENTER, 900 SW FIFTH AVENUE, PORTLAND, OR, 97204, US

(21) Appl. No.: 09/310,627

(22) Filed: May 12, 1999

(51) Int. Cl. H05K 7/20

(52) U.S. Cl. 361/704

(57) ABSTRACT

An improved electronic board assembly in which thermal conductivity is greatly increased through the use of thermally conductive plug placed within the vias. Within a via, usually having its walls coated with copper, a thermally conductive plug (such as copper) is placed; this plug is then secured to the via and the electronic board by flowing and solidifying solder around the plug. Due to the heightened thermal characteristics of the plug, heat is more efficiently wicked away from the electronic elements to a heat sink or heat dissipation mechanism.

### BACKGROUND OF THE INVENTION

This is a continuation-in-part of U.S. patent application Ser. No. 09/086,365, filed on May 28, 1999, and entitled “Packaging Power Converters”.

This invention is related to the packaging of electronic components. It involves a new method of transferring heat from power components in a given electrical circuit to a heat sink underneath the PCB.

One approach to packaging electric components in power converters (FIG. includes a housing which both encloses the components and means of heat extraction from the components. The house includes a non-conductive casing 5 and an aluminum heat-sinking base. A printed circuit board (PCB) 3 is mounted next to the upper wall 5a of the casing. Conductive pins 7 are attached directly to the PCB 3 and extend up through the wall 5a. Electronic components 9a, 9c are mounted to one or both sides of the PCB 3. Larger side components such as the transformer 9c are monted to the lower side for space reason. Power dissipating devices such as 9b are mounted directly on the base-plate 6 for better heat transfer. The power components 9b are electrically connected to the PBC by leads 12. Some of the power dissipating devices, 9d, are attached to the base plate via a thermally conductive insulator material 8. Structure 1 may be filled with an encapsulant, which acts as a heat spreader and provides mechanical support. In the case when a hard epoxy encapsulant is used a “buffer coating” material is used to protect some of the components.

One of the biggest problems associated with electronic instruments is the disposal of waste energy that the components generate. Often this is done through the use of a thermal sink which rests on a back portion of the electronic board. Heat from the electronic component is transferred from one side of the electronic board to the other through the use of a via.

Typically a via is a hole in the electronic board with often has its walls coated with copper. In production, the interior space of the via is filled with solder to provide for electrical connection and bonding. The vast majority of heat is transferred through the copper walls of the via.

While this technique works in general, it usually does not provide a very good cooling affect and often the electronic devices simply “cook” and become non-functional.

It is clear from the foregoing that there is a need for an improved cooling mechanism.

### SUMMARY OF THE INVENTION

This invention provides for an improved electronic board assembly in which thermal conductivity is greatly increased through the use of thermally conductive plug placed within the vias. Within a via, usually having its walls coated with copper, a thermally conductive plug (such as copper) is placed; this plug is then secured to the via and the electronic board by flowing and solidifying solder around the plug. Due to the heightened thermal characteristics of the plug, heat is more efficiently wicked away from the electronic elements to a heat sink or heat dissipation mechanism.

The thermal plug used within the via has thermal conductivity properties greatly improved over solder. Ideally, the thermal conductivity of the plug is at least 25 percent greater than solder. Thermal conductivity is the heat flow across a surface per unit time, divided by the negative of the rate of change of temperature with distance in a direction perpendicular to the surface. Those of ordinary skill in the art readily recognize a variety of such materials, including, but not limited to: substantially pure copper, substantially pure silver, and substantially pure aluminum.

For a PCB assembly, the electronic components are fastened to the top of the PCB. Typically, a large heat sink is positioned beneath the PCB. Under the electronic components are positioned one or more multiple vias which have their walls plated with copper. The vias of this invention are large enough to accept a large metal insert which forms a thermal slug. The thermal slub/metal insert is soldered to the PCB.

These metal inserts are much better thermal conductors than solder alone and provide for heightened conductivity so that heat from the electronic component is wicked to the heat sink or other mechanism used to discharge waste heat.

In the preferred embodiment, located directly underneath the PCB is an insulated multilayer substrate which aids in the transfer of heat form the PCB to the aluminum baseplate. This substrate is comprised of three different materials. The top layer is a thin copper foil. A portion of this copper foil is soldered to the under side of the PCB in the location where the metal inserts protrude through the PCB. Electrical isolation from the rest of the foil is provided by cutting a small island in the this location which is to be soldered to the metal inserts. The rest of the copper foil is not soldered to the bottom of the PCB, it relies on pressure to provide the coupling for heat transfer. The middle layer of the substrate is a thermally conducting material which electrically insulates the copper foil layer from the bottom aluminum plate.

The PCB along with the substrate, in the preferred embodiment, is mounted to an aluminum baseplate. Any conductive devices, such as ferrite cores, are ideally electrically isolated from the baseplate by means of a compressible thermoconductive material.

In another aspect of this invention, a packaging technology is described for power converters and power magnetics. The packaging methodology provides a compact, inexpensive, easy to manufacture. The invention features a package for electrical components held on a circuit board. In this packaging concept most of the power magnetic elements are constructed into the multilayers PCB. The windings of the magnetic elements such as transformer, inductors, and in some cases event signal transformers are incorporated in the multilayers PCB. The top layer and some portion of the bottom layer are also support for electronic components. The windings of the magnetic elements are contained inside of the multilayers PCB; the electronic components are placed on the top and on the bottom of the PCB. Some of the components are located on top of the windings and the interconnections between the magnetic elements. In this way the footprint of the magnetic elements is reduced to the footprint of the transformer core. The power-dissipating devices replaced on pads, which have a multitude of copper coated via to the other side of the PCB. The heat transferred to the other side of the PCB can be further spread using a larger pad or transferred to a metallic base-plate attached to the PCB through an isolating material. For air-cooled due to the limited surface of the heat spreader, an additional heat sink is attache to the heat spreader to increase its cooling area.

The unique aspect of this packaging concept is the fact that the magnetic element's windings are incorporated on the multilayers PCB construction which also serves as a support for power-dissipating components and some of the control components. The heat from the power-dissipating components is extracted through copper coated via which transfer the heat to the other side of the PCB. The heat is further transferred to a metal base plate connected to the PCB via a thermally conductive insulator. For airflow cooling applications the heat spreader connected to the thermal via can serve as a cooling surface. A heatsink can be also attached to the heat spreader to increased the heat dissipation area.

The invention, together with various embodiments thereof will be more fully explained by the accompanying drawings and the following description.

### DRAWINGS IN BRIEF

FIG. 1 is a cross-sectional side view of prior art components packaging.

FIG. 2 is a perspective exploded view of component packaging according to the invention.

FIG. 3A is a top view of the packaging with a detailed section of the magnetic' winding.

FIG. 3B is an enlarged view of a section of FIG. 3A FIG. 4A is a top view of the packaging with a detailed section of the cooling via.

FIG. 4C is a section of the packaging through the cooling via and through a magnetic element.

FIG. 4D is a broken view of the cooling via herein the insulator material penetrates in the cooling via.

FIG. 5A is the top view of the horizontal packaging with airflow cooling.

FIG. 6 is a top view of the packaging.

FIG. 6A is a cross-section of the package with cooling by airflow and cavities for magnetic cores.

FIG. 6B is a cross-section of the package with cooling by airflow and holes for magnetic cores.

FIG. 7A it is a perspective view of the power packages for airflow cooling.

FIG. 7B is a perspective view of the power packages for airflow cooling and additional heating applied to the multilayers circuit board.

FIG. 8 is a cross-section of the packaging connected to the motherboard.

FIG. 9 it is another embodiment of the present invention.

FIG. 10A is a high power magnetics package according to this invention.

FIG. 10B is a cross-section of the magnetic package presented in FIG. 10.

FIG. 11 shows a cross-sectional diagram of the completed PCB assembly using the improved thermal coupling apparatus for this invention.

FIG. 12 illustrates an embodiment of the invention which utilizes an additional heatsink.

FIG. 13 is still another embodiment of the invention in which the thermal slugs/inserts are wedged into the via.

FIG. 14 is still another embodiment of the thermal conductive aspect of this invention.

FIG. 15 illustrates an alternative embodiment in which the metal slugs extend past the PCB and are used to secure the heatsink to the PCB. FIG. 16 illustrates an embodiment of the invention having enhanced cooling capabilities.

### DRAWINGS IN DETAIL

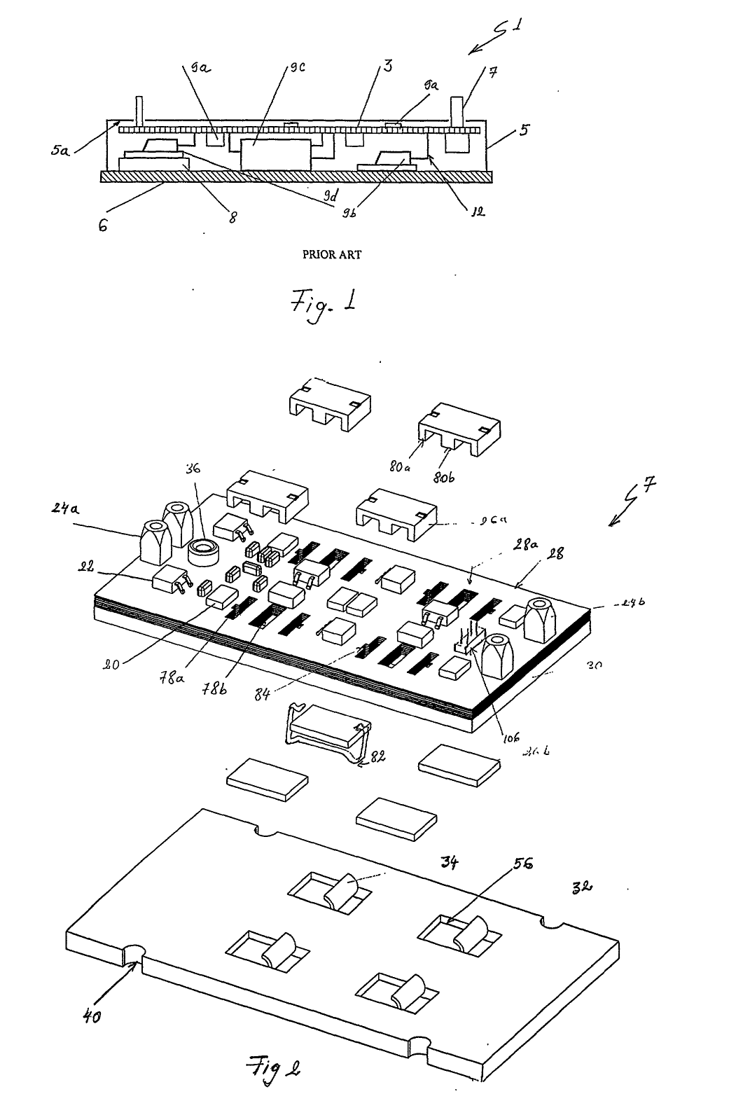

As noted and discussed earlier, FIG. 1, shows a prior art embodiment of the invention.

Referring to FIG. 2 in the packaging 7 provided by this invention, a power-dissipating electronic components 22 are located on the multilayer PCB 28 on top of the heat spreader pad 48, FIG. 4B. The heat spreader pad is connected to the copper coated via. A heat spreader 74, FIG. 4B, is connected on the backside of the PCB through the copper coated via 42. The copper coated via can be filled with solder or can be empty in which case the heat will be transferred through the metalization placed on the wall of the via. The metalization is formed by copper deposit during the plating process associated with the manufacturing process of the PCB. As a result of the plating process the wall of the via is covered with copper. The via can be also filled with a thermally conductive material 30a as is presented in FIG. 4D. The isolated material 30 placed under the PCB 28 under pressure will penetrate through the via filling the space. In between the 28 and the metal base plate 32 an insulator material with good thermal conductivity characteristics 30 is placed. In this way the heat from the power dissipating components 22, is transferred through the copper pad 48 on which the power dissipating device is mounted, to the copper coated via 42 to the other side of the PCB, 28B, to the heat spreader 74. The heat is further transferred through the thermally conductive insulator material 30 to the metal plate 32. In the case wherein the insulator material 30 will penetrate through the copper coated via 42 the surface contact will increase and as a result the thermal transfer from the copper pad 48 to the metal plate 30 will be improved.

The main embodiments of this invention is the magnetic elements implementation in the multilayers PCB and the means in which the heat is extracted form the power dissipating devices, from the magnetic winding 50, (FIG. 3A and FIG. 3B), from the magnetic core 26A and 26B, and the low power dissipation devices 20 to the baseplate 32. To increase the power density, some components 88 are mounted on top of the multilayers PCB 28a, on top of the windings 50 embedded in the inner layers of the multilayers PCB 28. In this way the footprint of the magnetic element is reduced to the footprint of the magnetic core 26a.

The main embodiment of this invention is the fact that the magnetics elements are implemented in the multilayers PCB 28. In the prior art the magnetic elements were discrete devices which were connected to the PCB by means of through hole or surface mounted pins. The presence of the connecting pins increases the coast of the magnetic element and it reduces the reliability of the magnetic device due to the mechanical failure of the pins. The interconnection pin can be bent or broken easily. The presence of the interconnection pins adds supplementary stray inductance in series with the transformer. This will negatively impact the electrical performance of the circuit. In most of the applications the energy contained in this parasitic inductance is dissipated, reducing the parasitic inductance of the inter connection pins can increase to voltage or current stress on the electrical components.

In this invention the magnetic elements have the windings embedded inside of the multilayers PCB. The interconnection between the magnetic elements and between the magnetic elements and the electronic components are made through copper pads etched in the layers of the multilayers PCB and through the copper coated via 42 in the multiyear PCB 28. This allows the use of more complex winding arrangements and allows the use of more magnetic elements on the same multilayers PCB construction. The interconnections of these magnetic elements are made within the multilayer PCB. The converter will contain a number of smaller magnetic elements achieving a low profile package. The magnetic cores 26A and 26b will penetrate through multilayers PCB via the cutouts 78a and 78b fitted for the outer legs 80a and inner legs 80b. The magnetic sections 26a and 26b can be glued together or attached via a spring clips 82. To accommodate the spring clip additional cutouts in the PCB 84 are produced. The bottom side of the magnetic core 26b, will surface on the back of the PCB. To be able to accommodate the magnetic cores 26b cutouts 86 are made through the insulator material 30. In most of applications the thickness of the insulator material is smaller than the height of the magnetic core. To accommodate the magnetic core 26b, cavities 56, are produced into the base plate 32. Due to the fragile characteristic of the magnetic cores, a soft pad 56, with small thermal impedance is placed under the magnetic core 26b in the cavity. The pad 56, will dampen the vibration of the magnetic core, The low thermal impedance of the pad 56, will also offer a cooling path for the magnetic core. In some applications wherein insulation has to be achieved to the base plate, the pad, 56 have to have insulation properties.

The entire structure 7 is press together in a way that the magnetic core 26b will be placed on top of the pad 56. The thickness of the pad has to chosen in a way that the metallic plate 32 makes good contact with the insulator 30. The insulator 30, is pressed between the PCB 28 and metal plate 32. The permanent attachment can be done in several ways. In the preferred embodiment the isolator material 30 has adhesive properties stimulated by a curing process at higher temperature. After the curing process the insulator created a bound between the PCB 28, and the metal plate 32. In applications wherein the structure 28 is connected to anther plate, the flanges 40 can accommodate screws.

A cross-section of the structure 7, mounted is presented in FIG. 4C. A section of the structure is blown in FIG. 4B. In the cross-section of the structure 90 is presented the location of a power dissipation device on top of the copper pad 48, and the coated via 42. The copper coated via carry the heat to the heat spreader 74. The heat is further transferred via the thermally conductive insulator 30 to the metal plate 32.

A second cross-section of the mounted structure 7, is presented in FIG. 4C. In the cross-section, 92, is presented the upper section of the magnetic core 26a, the bottom section of the magnetic core 26b, the pad under the magnetic core 34 located in the cavity 56. The heat generated in the magnetic core 26 is transferred to the base plate through the pad 34. For components which have to have a temperature close to the temperature of the base plate, copper coated via are placed under the components or to the traces and pad connected to the components. In this way low thermal impedance is achieved to the base plate. With low thermal impedance to the base plate, the temperature rise of these components will be small.

Using screws, clips, or different means of applying pressure to the structure 7 can also make the attachment of the PCB 28, to the isolator 30 and the base-plate 32. In some applications the cutouts in the metallic plate 32 can penetrate through the plate. The magnetic cores 26b will be visible from the bottom side of the metallic plate. For protecting the magnetic cores 26b, soft epoxy material can cover the remaining cavity in between the magnetic core and the surface of the base plate 32. In some application that cavity can be left open.

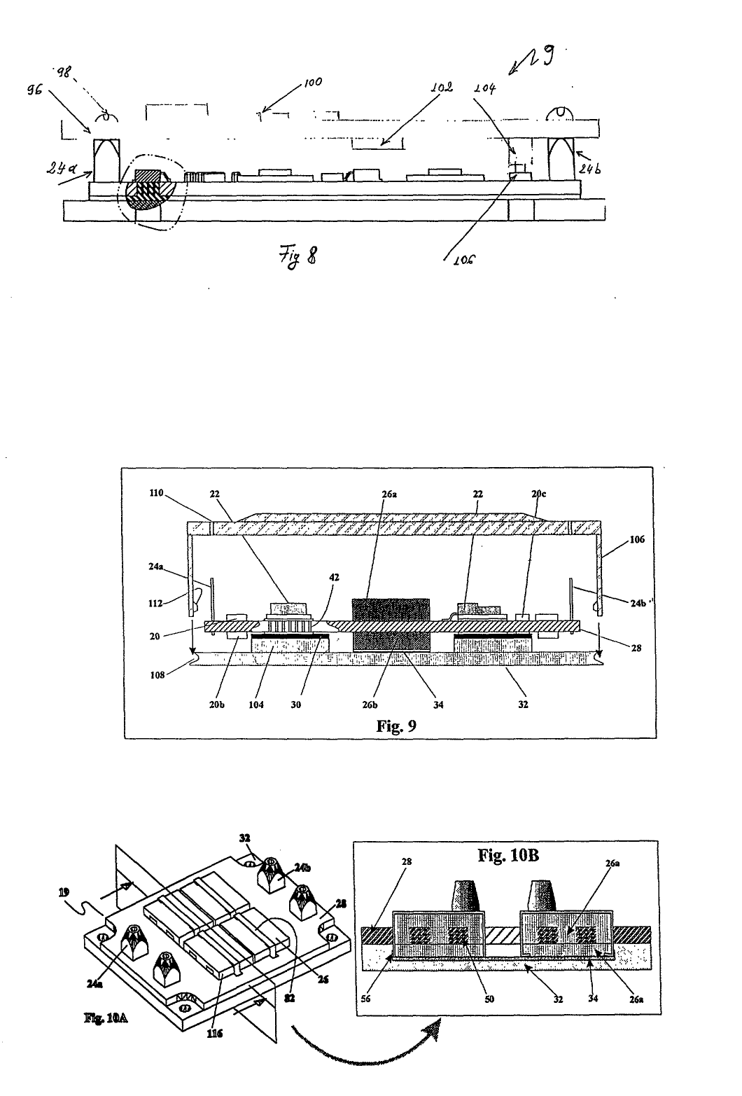

In FIG. 8 is presented a structure 9 wherein the package 7 is attached to a motherboard 96. The attachment is done through the power connectors 24a and 24b. The power connectors are attached to the motherboard 96 through screws 98. There is a signal connector 106 located on the structure 7. The signal connector 106 is connected to the matching signal connector 104 located on motherboard 96. More than one structure 7 can be connected to the same motherboard 96. On the motherboard 96 there are additional components 100 and 102. This structure it is suitable for systems wherein only the power train and some control functions are located on the structure 7. Some of the control section components, supplementary logic circuits and EMI filters are located on the motherboard. The bottom layer of the motherboard 96 may contain copper shields to protect the noise sensitive components. The noise sensitive components are located on the motherboard and the power dissipate components, some control components and the magnetics are located on the structure 7.

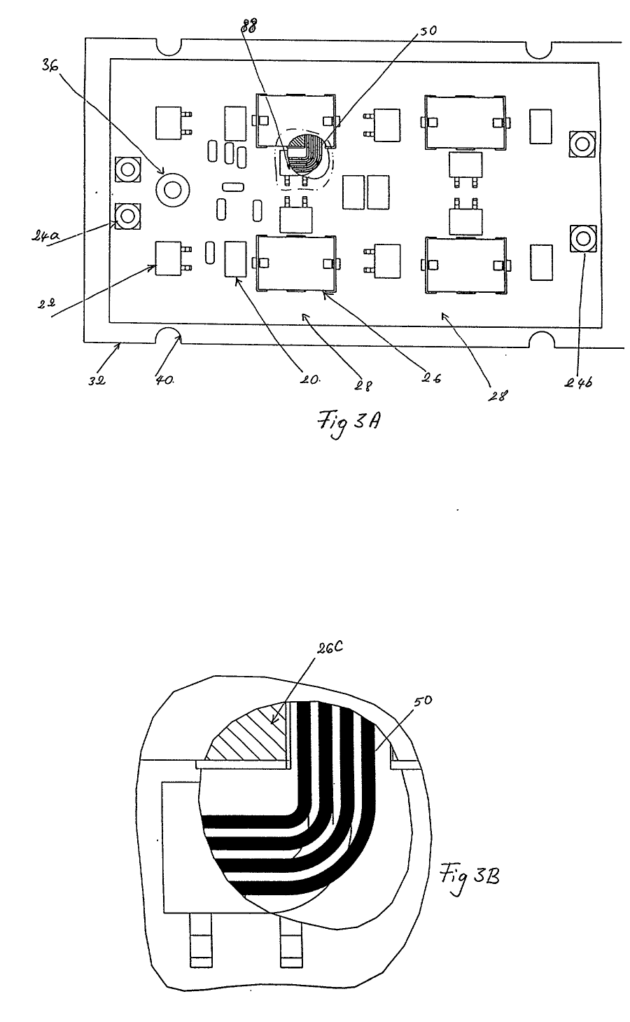

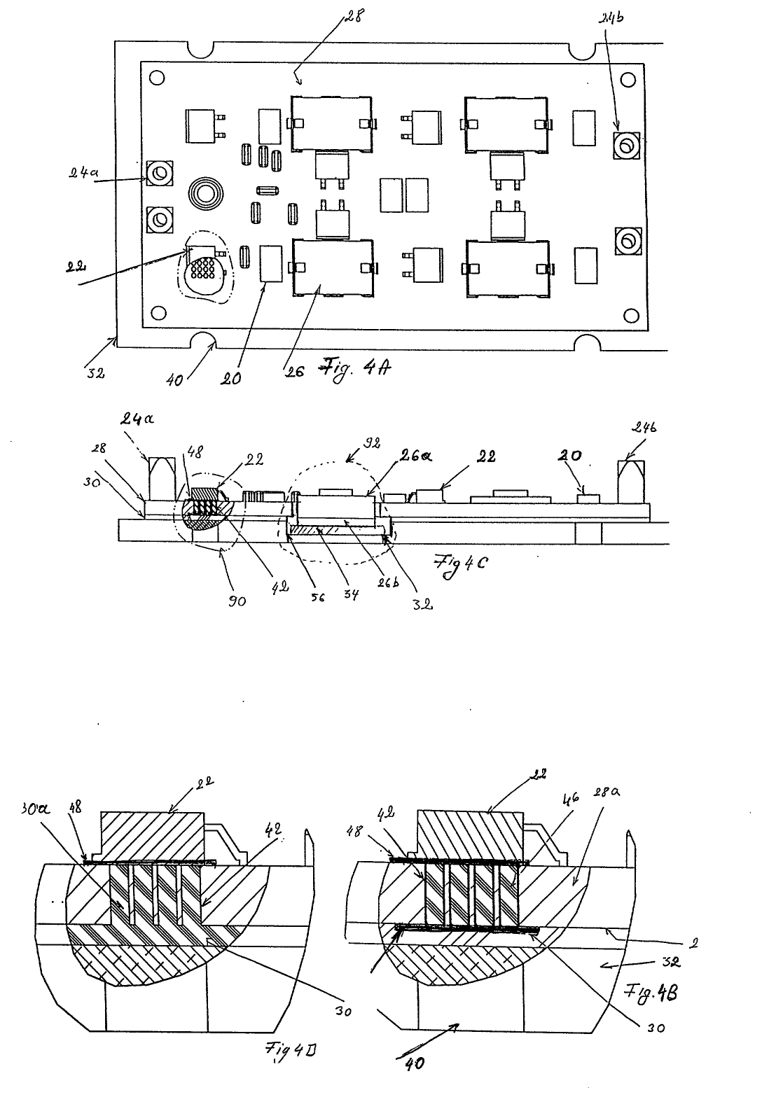

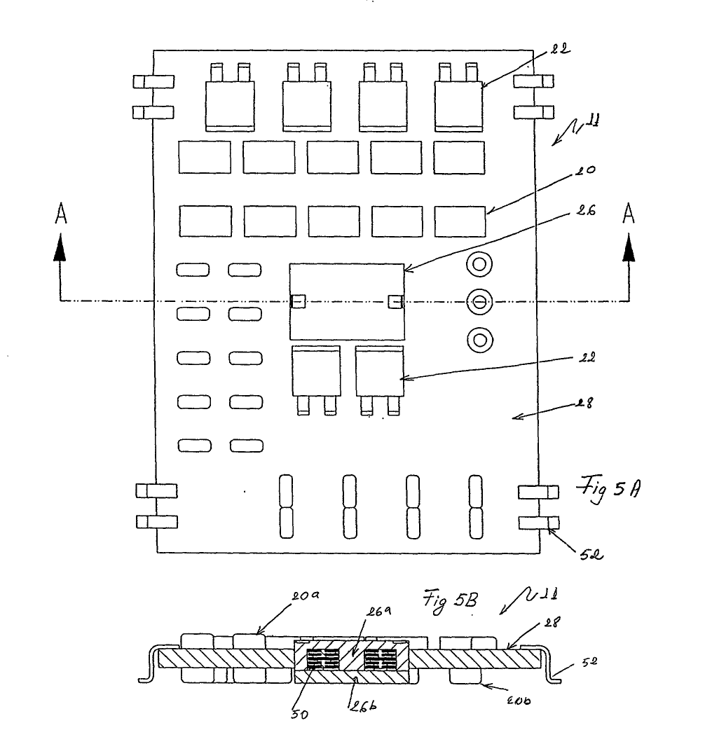

In FIGS. 5a and 5b is presented a packaging structure 11. In this structure the magnetic element has its winding embedded within the multilayers PCB 28 as it is in structure 7. The components are located on both sides of the multilayers PCB. This packaging structure applies to low power dissipation application wherein there is an airflow. The entire surface of multilayers PCB 28 becomes a heatsink. The structure 11 is connected to the other circuitry via the pins 52.

In FIG. 7A is depicted a power system which contains several packaging structures 15. The structure 15 include the magnetic elements 26, the power dissipating components 22, the low power dissipation components 20, similar with structure 7. The main difference is that there is not an isolator 30, and a base plate 32. The cooling is accomplished by the air, which flows in between the packaging structures 15. The entire surface of 15 becomes a heatsink. The structures 15 are connected to the motherboard 64 through signal connectors 70a, and power connectors 70b.

Supplementary components are located on the motherboard 64.

In FIG. 7B the motherboard 64 is connected to two packaging structures 17. These packaging structures contain the same components as structure 15 with an additional heat sink 58 attached to the multilayers PCB 28 through the insulator 30.

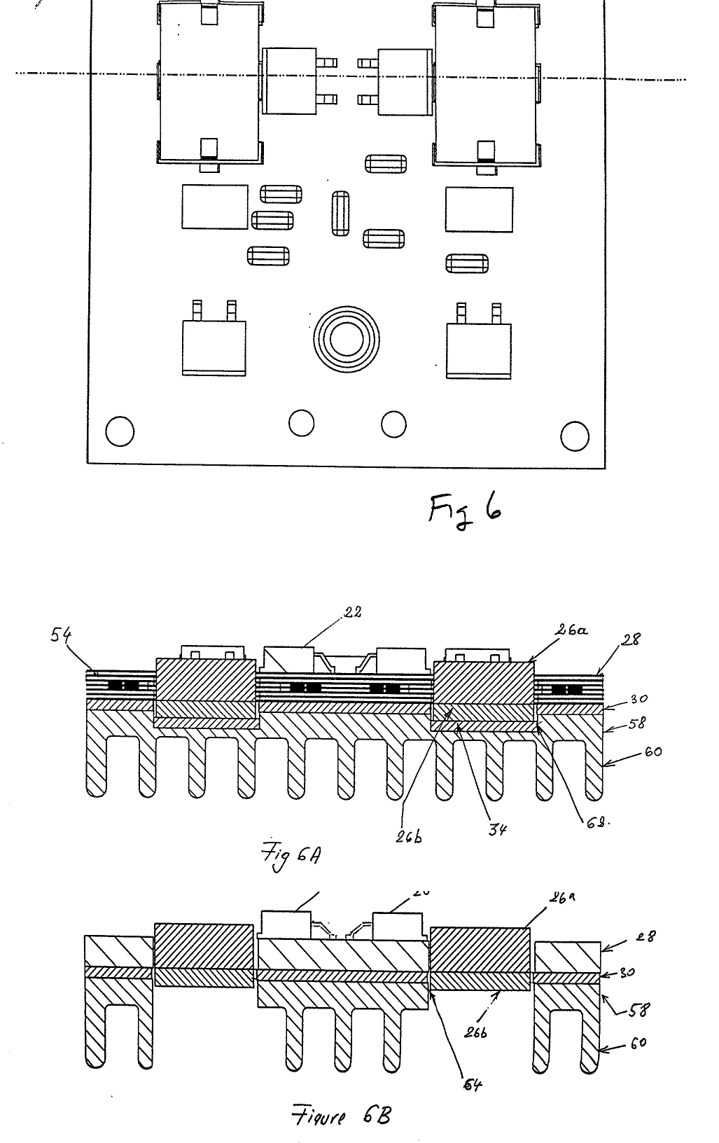

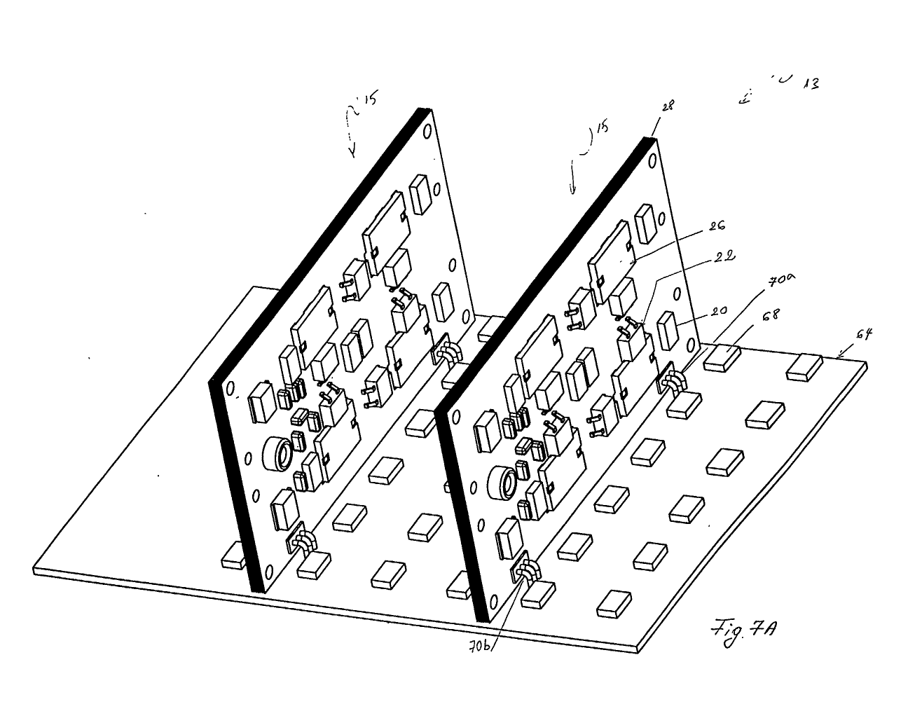

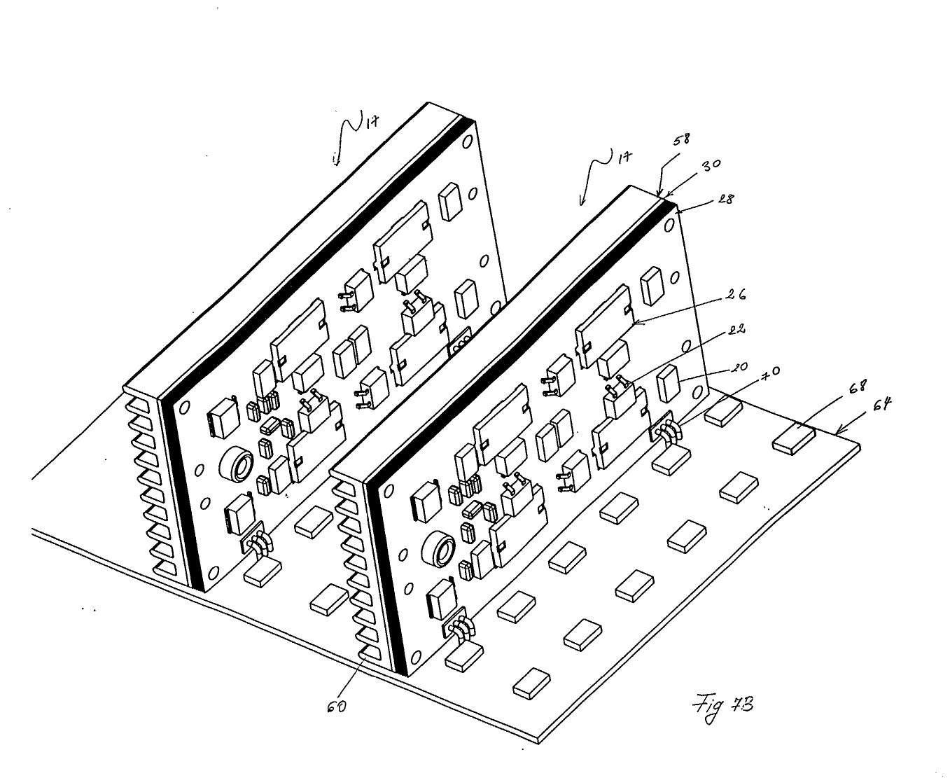

Two types of heatsink construction are presented in FIG. 6A and ˆ B. In FIG. 6A the heatsink 58 has air fins 60 and cavities 62. In the cavities a soft compressible material 34, with low thermal impedance is placed. The insulator with low thermal impedance 30 is placed between the multilayers PCB 28 and the base plate 58. The magnetic core 26b is cooled via the soft pad 34. The power-dissipation devices are cooled though copper coated via like in structure 7.

In FIG. 6B the heatsink 58 with air fins 60 has cutout-outs 64 to accommodate for the magnetic core 26b. The cooling of the magnetic core 26a and 26b is accomplished by the airflow. The cooling of the power-dissipation devices is done through copper coated via 42.

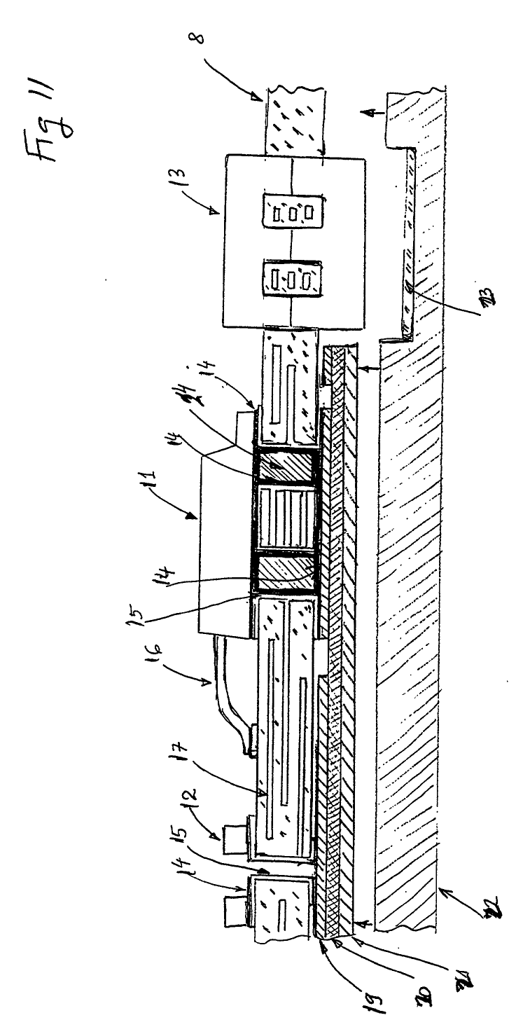

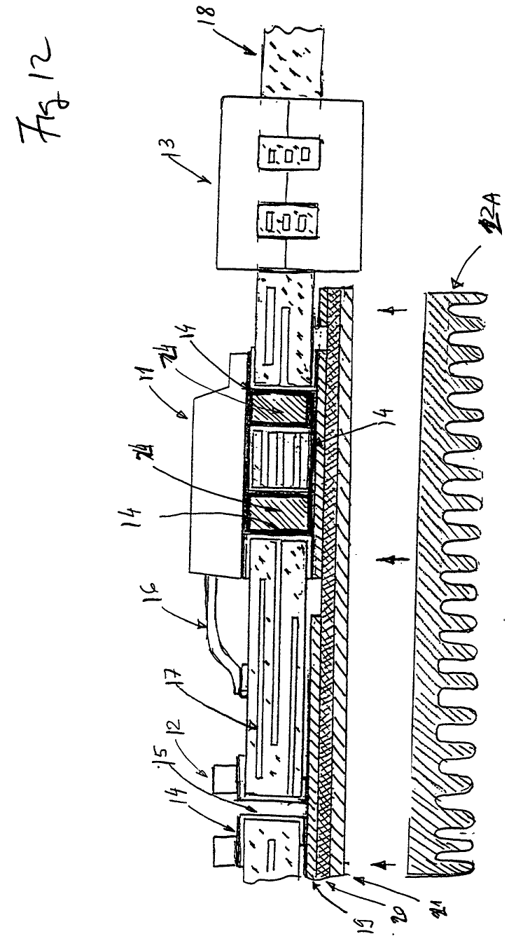

In FIG. 9 is presented a packaging structure wherein the metal plate 32 does not contain cavities. It has elevated sections 104, which makes contact with the thermally conductive insulator 30, which is placed under the multilayers PCB 28. The elevated sections of the metal plate 104 are primarily placed under the power dissipated devices 22 and other low dissipation components 20c which require to have a temperature close to the base plate temperature. The thermally conductive soft pad 34, on the base plate 32 supports the magnetic core 26a and 26b. The height of the elevated section of the baseplate 104, are function of the height of the magnetic core 26b and the compression ratio of the pad 34. The advantage of the packaging concept is the fact that more components can be mounted on the multilayers PCB on the backside 20b. This package is suitable for power converters, which contains all the control and signal interface functions. The interconnection pins 24a and 24b will provide the power and signal connections to the outside word. The cover 106 contains holes 110 to accommodate the interconnection pins 24a and 24b.

For the purpose of attaching case 106 to the baseplate 32 (FIG. 9) teeth 112 are formed along the lower edge of the case. A matching grove 108 is undercut into the base plate 32.

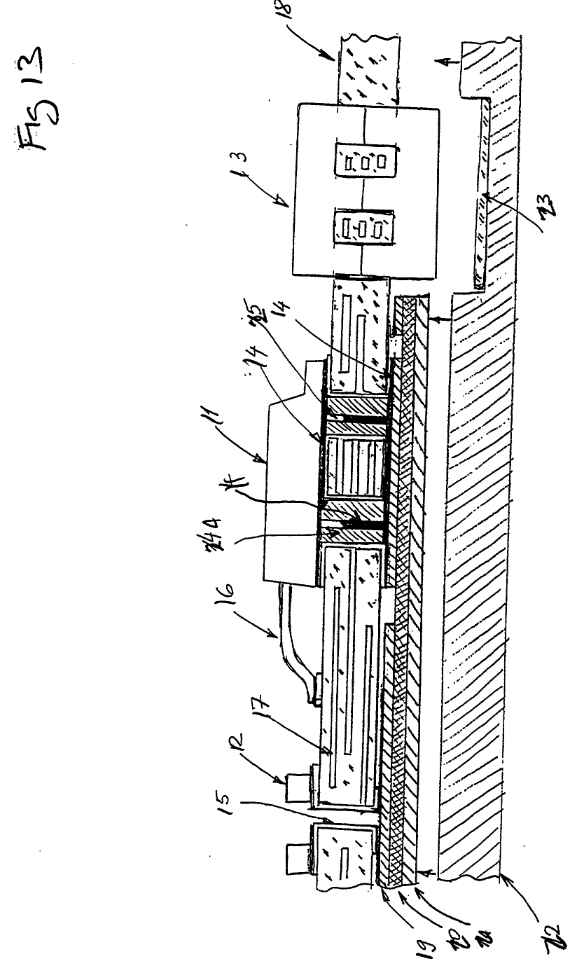

In FIG. 10A is presented a high power magnetic structure wherein the magnetic core is formed by several small magnetic cores 26. A cross-section through the structure 19 is presented in FIG. 10B. The windings 50 of the magnetic structure are embedded in the multilayer PCB layers. The cutout 116 in the multilayers PBC 28 are made to accommodate the magnetic cores 26. Power connectors are inserted in the multilayers PBC 28. The connectors 24a and 24b are connected to the windings 50. The cores 26a and 26b are attached together via the clips 82. The multilayers PCB 28 wherein the windings 50 are embedded into also offers supports for the magnetic cores 26. A cavity 56 is placed in the base plate 32. A thermally conductive soft pad is placed under the magnetic core 26b on top of base plate 32.

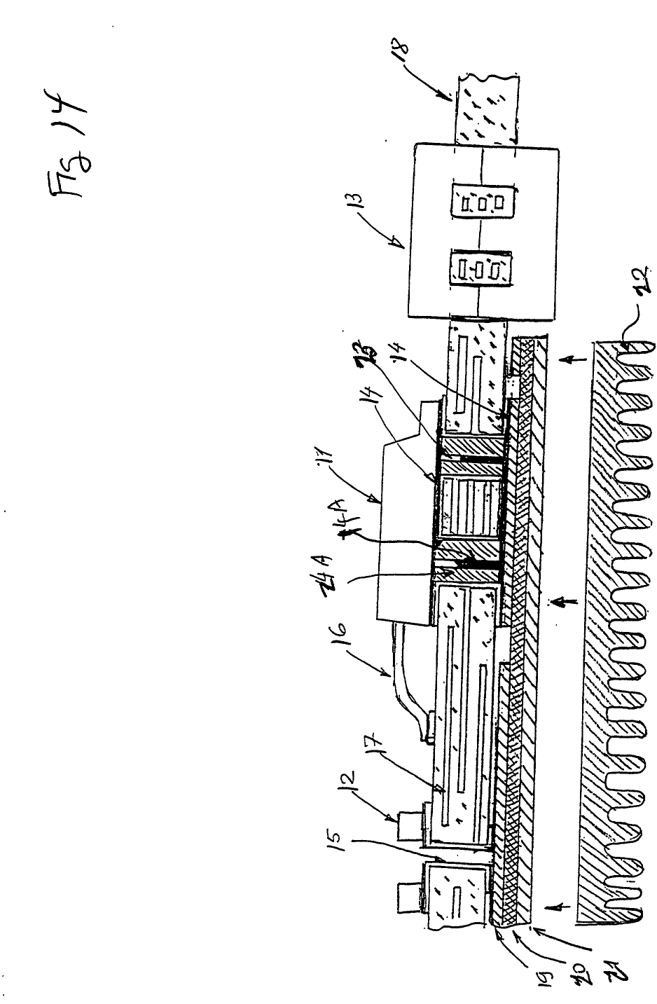

FIG. 11 shows a cross-sectional diagram of the completed PCB assembly using the improved thermal coupling apparatus for this invention.

The basic components for this embodiment are: power device 11, other devices 12, magnetic cores 13, solder 14, via with plated copper walls 15, legs of the power device 16, inner layers 17, printed circuit board (PCB) having multilayers 18, copper foil 19, insulation material 20, metal plate 21, addtional heat sink 22, compressible thermoconductive material 23, and metal insert 24.

Electrical components (11, 1 2 and 13) are assembled on a multilayer PCB (18). Under the power device (11) are one or more multiple vias (15) which are plated with copper. Vias 15 are large enough to accept a large metal insert (24) which is soldered to the PCB. These metal inserts are much better thermal conductors than solder alone.

In this context, the thermal insert/plug 24 used within the via has thermal conductivity properties improved over solder. Ideally, the thermal conductivity of the plug is at least 25 percent greater than solder. Thermal conductivity is the heat flow across a surface per unit time, divided by the negative of the rate of change of temperature with distance in a direction perpendicular to the surface. Those of ordinary skill in the art readily recognize a variety of such materials, including, but not limited to: substantially pure copper, substantially pure silver, and substantially pure alumina.

Located directly underneath the PCB is an insulated multilayer substrate which aids in the transfer of heat form the PCB to the aluminum baseplate. This substrate is comprised of three different materials. The top layer is a thin copper foil (19). A portion of this copper foil (19) is soldered to the under side of the PCB in the location where the metal inserts (24) protrude through the PCB. Electrical isolation from the rest of the foil is provided by cutting a small island in the this location which is to be soldered to the metal inserts (24). The rest of the copper foil (19) is not soldered to the bottom of the PCB, it relies on pressure to provide the coupling for heat transfer. The middle layer of the substrate (20) is a thermally conducting material which electrically insulates the copper foil layer from the bottom aluminum plate (21).

The PCB along with the substrate may then be mounted to an aluminum baseplate (22). Any conductive devices such as ferrite cores (23) may be electrically isolated from the baseplate by means of a compressible thermoconductive material.

The method of operation for this system is to solder the power device to the top of the PCB, on top of the soldered metal inserts. The heat generated during electrical operation of the circuit is easily transmitted through the metal inserts. The heat is spread out over a large surface area through the insulation material to the aluminum plate and to the baseplate.

The power device 11 is optionally a die placed on the metal insert 24 and with bond wire connected to the multilayer PCB.

FIG. 12 illustrates an embodiment of the invention which utilizes an additional heatsink.

As before, electrical components (11, 12 andl3) are assembled on a multilayer PCB (18). Under the power device (11) there are multiple vias (15) which are plated with copper.

These improved vias 15 are larger than traditional vias to accept the metal insert/slug 24. Solder provided during the manufacture of the PCB (18) flows around the insert/slug 24 to bond the assembly together.

Located directly underneath the PCB is an insulated multilayer substrate which aids in the transfer of heat from the PCB to the aluminum heatsink. This substrate is comprised of three different materials. The top layer is a thin copper foil (19). A portion of this copper foil (19) is soldered to the under side of the PCB (18) in the location where the metal insert protrude through the PCB (18).

Electrical isolation from the rest of the foil is provided by cutting a small island in this location which is to be soldered to the metal inserts/slugs 24. The rest of the copper foil (19) is not soldered to the bottom of the PCB, it relies on pressure to provide the coupling for heat transfer. The middle layer of the substrate (20) is a thermally conducting material which electrically insulates the copper foil layer from the bottom aluminum plate conducting material which electrically insulates the copper foil layer from the bottom aluminum plate (21). The PCB along with the substrate is then be mounted to an aluminum heatsink (22A).

The method of operation for this system is to solder the power device to the top of the PCB above the soldered metal inserts. The heat generated during electrical operation of the circuit is transmitted through the metal inserts to the copper foil island underneath. This island is large compared to the metal inserts to allow for greater thermal conductivity. The heat is spread out over a large surface area through the insulation material to the aluminum plate and to the heatsink.

The size of the copper foil layer 19 underneath the metal insert is tailored to control the capacitance between the power device 11 and heat sink 22.

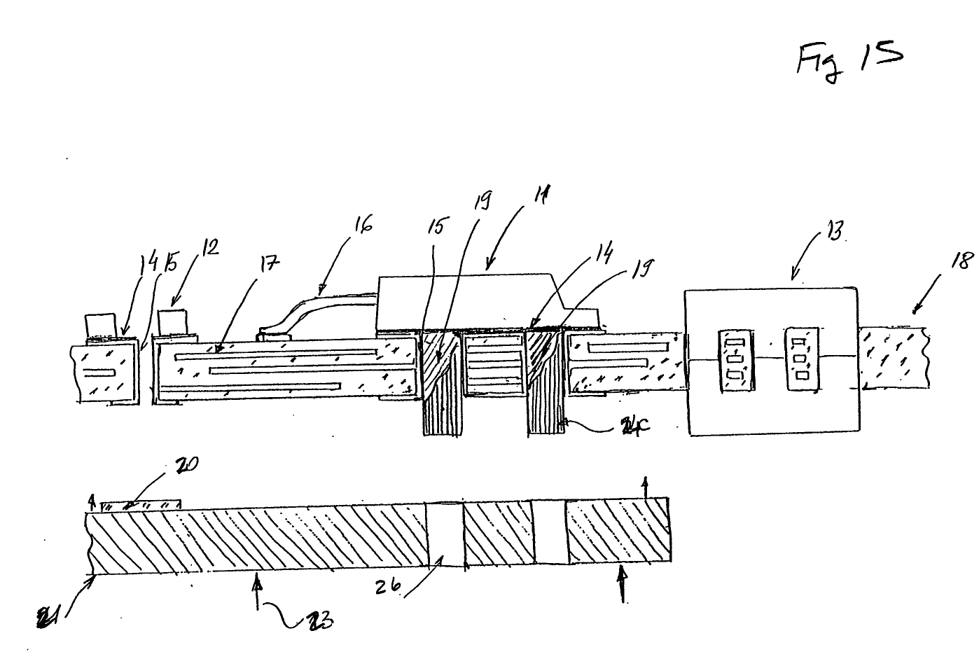

FIG. 13 is still another embodiment of the invention in which the thermal slugs/inserts are wedged into the via.

In this embodiment, the metal inserts/slugs 24A are also unique in that they have a small through hole which extends from its top to bottom. This allows for a good solder flow due to a capillary action when the insert is soldered from a portion of the underlying multilayer substrate to the power device on top side of the PCB. The metal inserts/slugs 24A have a diameter greater than the diameter of the via with its walls coated with copper.

This requires the metal insert/slug 24A to be “wedged” into the via. The solder flows through the internal channel to connect the top of PCB 18 to the bottom.

The PCB along with the substrate is mounted to an aluminum baseplate (22). Any conductive devices such as ferrite cores (13) may be electronically isolated from the baseplate by means of compressible thermoconductive material.

The method of operation for this system is to solder the power device to the top of the PCB, on top of the pressure fitted metal inserts. The heat generated during electrical operation of the circuit is transmitted through the metal inserts so there is no decrease in the thermal resistivity of this junction. The heat is spread out over a large surface area through the insulation material to the aluminum plate and to the baseplate.

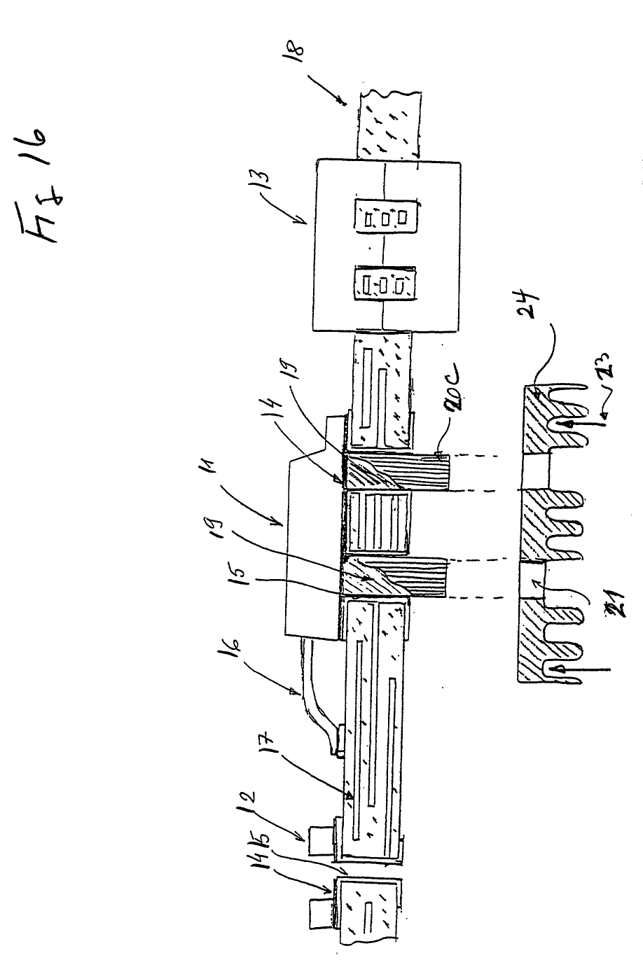

FIG. 14 is still another embodiment of the thermal conductive aspect of this invention.

As with the prior embodiments, the embodiment of FIG. 14 includes the electrical components (11, 12 and 13) are assembled on a multilayer PCB (18). In this embodiment, the metal inserts (24A) have a small through hole 14A which extends from its top to bottom. This allows for a good solder flow due to a capillary action when the insert is soldered from a portion of the underlying multilayer substrate to the power device on the top side of the PCB (18).

The substrate is located directly underneath the PCB and its function is to aid in the transfer of heat from the PCB to the aluminum heatsink. This substrate is comprised of three different materials. The top layer is a thin copper foil (19). The PCB along with the substrate is mounted to an aluminum heatsink (22).

The method of manufacture for this system is to solder the power device to the top of the PBC, on top of the pressure fitted metal inserts (24A). The heat generated during electrical operation of the circuit is transmitted through the metal inserts (24A). The heat generated during electrical operation of the circuit is transmitted through the metal inserts to the copper foil island underneath. This island is large compared to the metal inserts so there is no decrease in the thermal resistivity of this junction. The heat is spread out over a large surface area through the insulation material to the aluminum plate and to the baseplate.

FIG. 15 illustrates an alternative embodiment in which the metal slugs extend past the PCB and are used to secure the heatsink to the PCB.

In this embodiment, metal inserts/slug 24C have a length sufficient to extend through the PCB and also through holes 26 of heat sink 23.

The PCB assembly is mounted to an aluminum baseplate (23), acting as a heatsink, which has holes (26) to accompany the metal inserts (24C). A tight pressure fit is required for good thermal transfer. Any conductive devices such as ferrite cores (13) or smaller electrical vias (15) may be electrically isolated from the base plate by means of a compressible thermoconductive material.

Manufacture of this embodiment is to solder the power device to the top of the PCB, on top of the pressure fitted metal inserts. The heat generated during electrical operation of the circuit is transmitted through the metal inserts directly to the aluminum baseplate underneath.

Metal insert/slug 20C have a contoured exterior wall to allow liquid solder to flow therebetween to provide for bonding and also for electrical conductivity.

FIG. 16 illustrates an embodiment of the invention having enhanced cooling capabilities.

In this embodiment, metal inserts/slugs (20C) are elongated to pass through PCB (18) and engage cooling vane 24. As with the illustration of FIG. 15, the embodiment of FIG. 16 uses metal inserts/slugs 20C which mechanically engage the walls of vias (14) and the holes 21 within the cooling vane 24. Metal insert/slug 20C have a contoured exterior wall to allow liquid solder to flow therebetween to provide for bonding and also for electrical conductivity.

It is clear from the foregoing that the present invention provides for greatly enhanced cooling capabilities of an electronic board.

What is claimed is:

1. A thermal via assembly for a primary electronic board comprising:
a) a via extending through said primary electronic board, walls of said via coated with copper;
b) a heat conductive plug extending through said via; and,
c) solder connecting said heat conductive plug to the walls of said via.

2. The thermal via assembly according to claim 1, wherein said heat conductive plug has a thermal conductance at least twenty five percent greater than solder.

3. The thermal via assembly according to claim 1, wherein said heat conductive plug is substantially pure copper.

4. The thermal via assembly according to claim 1, further including a secondary electronic board, and wherein said secondary electronic board is secured to the primary board by said solder.

5. The thermal via assembly according to claim 3,
a) further including a secondary electronic board having a via therein, the via of said secondary electronic board aligned with the via of said primary electronic board; and,
b) wherein said heat conductive plug extends through the via of said secondary electronic board.

6. The thermal via assembly according to claim 3,
a) further including a heat sink having a via therein, the via of said heat sink aligned with the via of said primary electronic board; and,
b) wherein said heat conductive plug extends through the via of said heat sink.

7. The thermal via assembly according to claim 6, wherein said heat sink and said heat conductive plug are adapted to conduct electrical energy in concert.

8. The thermal via assembly according to claim 3, wherein said heat conductive plug has a diameter less than a diameter of said via with said walls coated with copper.

9. The thermal via assembly according to claim 3, wherein said heat conductive plug has a diameter slightly greater than a diameter of said via with said walls coated with copper.

10. The thermal via assembly according to claim 9, wherein an outer surface of said heat conductive plug is grooved to allow said solder, when in a liquid state, to pass through said grooves.

11. The via assembly according to claim 3, wherein said heat conductive plug has an internal channel extending through said copper plug, said internal channel having sufficient diameter to allow solder in a liquid state to flow therethrough.

12. A thermal conductive channel for a primary electronic board comprising:
a) a via extending through said primary electronic board;
b) a heat conductive plug extending through said via; and,
c) solder connecting said heat conductive plug to said via.

13. The thermal conductive channel according to claim 12, wherein said heat conductive plug has a thermal conductance at least twenty five percent greater than solder.

14. The thermal conductive channel according to claim 12, wherein said heat conductive plug is substantially pure copper.

15. The thermal conductive channel according to claim 14,
a) further including a secondary electronic board having a via therein, the via of said secondary electronic board aligned with the via of said primary electronic board; and,
b) wherein said heat conductive plug extends through the via of said secondary electronic board.

16. The thermal via assembly according to claim 14, wherein said heat conductive plug has a diameter less than a diameter of said via with said walls coated with copper.

17. The thermal conductive channel according to claim 14, wherein said heat conductive plug has a diameter slightly greater than a diameter of said via with said walls coated with copper.

18. The thermal conductive channel according to claim 17, wherein an outer surface of said heat conductive plug is grooved to allow said solder, when in a liquid state, to pass through said grooves.

19. The via assembly according to claim 14, wherein said heat conductive plug has an internal channel extending through said copper plug, said internal channel having sufficient diameter to allow solder in a liquid state to flow therethrough.

20. An electronic board assembly comprising:
a) an electronic board adapted to support electronic elements;
b) an electronic element connected to said electronic board;
c) a via extending through said electronic board under said electronic element, walls of said via coated with copper;
d) a heat conductive plug extending through said via; and,
e) solder connecting said heat conductive plug to the walls of said via and to said electronic element.

21. The electronic board assembly according to claim 20, further including a heat dissipating mechanism attached to a surface of said electronic board opposite said electronic element, said heat dissipating mechanism in thermal connection with said heat conductive plug.

22. The electronic board assembly according to claim 20, wherein said heat conductive plug has a thermal conductance at least twenty five percent greater than solder.

23. The electronic board assembly according to claim 20, wherein said heat conductive plug is substantially pure copper.

24. The electronic board assembly according to claim 23, wherein said heat conductive plug has a diameter less than a diameter of said via with said walls coated with copper.

25. The electronic board assembly according to claim 20, wherein said heat conductive plug has a diameter slightly greater than a diameter of said via with said walls coated with copper.

26. The electronic board assembly according to claim 25, wherein an outer surface of said heat conductive plug is grooved to allow said solder, when in a liquid state, to pass through said grooves.

27. The via assembly according to claim 22, wherein said heat conductive plug has an internal channel extending through said copper plug, said internal channel having sufficient diameter to allow solder in a liquid state to flow therethrough.
